(19) United States
(12) Patent Application Publication
(10) Pub. No.: US 2006/0227837 A1
(43) Pub. Date: Oct. 12, 2006

(54) Quantum dot vertical cavity surface emitting laser and fabrication method of the same

(75) Inventors: Eun-kyung Lee, Suwon-si (KR); Byoung-Iyong Choi, Seoul (KR)

Correspondence Address: BUCHANAN, INGERSOLL & ROONEY PC, POST OFFICE BOX 1404, ALEXANDRIA, VA, 22313-1404, US

(73) Assignee: Samsung Electronics Co., Ltd., Suwon-si (KR)

(21) Appl. No.: 11/285,176

(22) Filed: Nov. 23, 2005

(30) Foreign Application Priority Data
Feb. 15, 2005 (KR) 10-2005-0012419

(51) Int. Cl. H01S 5/00

(52) U.S. Cl. 372/50.124

(57) ABSTRACT

A quantum dot vertical capacity surface emitting laser (QD-VCSEL) and a method of manufacturing the same are provided. The QD-VCSEL includes a substrate, a lower distributed brag reflector (DBR) mirror formed on the substrate, an electron transport layer (ETL) formed on the lower DBR mirror, an emitting layer (EML) formed of nano-particle type group II-VI compound semiconductor quantum dots on the ETL, a hole transport layer (HTL) formed on the EML, and an upper DBR mirror formed on the HTL.

### CROSS-REFERENCE TO RELATED PATENT APPLICATION

This application claims the benefit of Korean Patent Application No. 10-2005-0012419, filed on Feb. 15, 2005, in the Korean Intellectual Property Office, the disclosure of which is incorporated herein in its entirety by reference.

### BACKGROUND OF THE DISCLOSURE

1. Field of the Disclosure

The present disclosure relates to a quantum dot vertical cavity surface emitting laser and a fabrication method of the same, and more particularly, to a quantum dot vertical cavity surface emitting laser having an excellent light emitting efficiency and wavelength characteristic and ease of manufacture, and to a fabrication method of the same.

2. Description of the Related Art

Quantum dots may have well separated energy gaps and trap carriers in a three-dimensional arrangement, thus the quantum dot structure has excellent thermal stability when utilized as an optical device when compared to a quantum well structure. A self-assembled quantum dot growth method is currently being actively studied as a method of forming such quantum dot.

In the self-assembled quantum dot growth method, a material having a larger lattice constant than a substrate or a buffer layer is deposited on the substrate or the buffer layer by a metal organic chemical vapor deposition method. In this instance, the material having the larger lattice constant can be grown as a thin two-dimensional crystal layer to the thickness of the first 2-5 monolayers (ML); however, when the thickness of the layer is increased, the material is grown as a three-dimensional crystal layer in order to relieve the stress energy. The size of the three-dimensional crystal becomes 20 to 60 nm; thus the crystals can be used as the quantum dots. Such a method is mainly used for a material having a lattice mismatch of 3 to 7%.

After the quantum dots are formed, the carriers of the quantum dots are trapped by growing the material same as the substrate or the buffer layer on the top of the quantum dots, in order to use the quantum dots as a device. The layer grown on the quantum dots is referred to as a copping layer. Such a self-assembled quantum dot method is applied to optical devices, such as a quantum dot laser, an amplifier, and an optical switch.

The full width half maximum of the quantum dot light emitting wavelength denotes the uniformity of the quantum dots. In other words, as the full width half maximum is smaller, the uniformity of the quantum dots is regarded as being satisfactory. The degree of the uniformity of the quantum dots operates as a standard when applying the quantum dot layer as a device. However, when a quantum dot device is used, it is difficult to control the wavelength compared to the quantum well structure. In addition, the size distribution of the quantum dots is uniform, resulting in the large full width half maximum.

U.S. Pat. No. 6,782,021 B2 discloses a structure of a quantum dot vertical capacity surface. However, since the quantum layer is formed by a crystal method, in other words an epitaxal growth method, the possible material of DBR and the other substrate would be limited. More specifically, since the refractive indexes of the material layers, which form the DBR, are small, the number of the material layers is increased, resulting in an increase in the size of the VCSEL device. In addition, the manufacturing method and the manufacturing cost for the VCSEL device are increased.

### SUMMARY OF THE DISCLOSURE

The present invention may provide a quantum dot vertical capacity surface emitting laser (QD-VCSEL) having excellent light emitting efficiency and the wavelength characteristic which is easily manufactured and a fabrication method of the same.

According to an embodiment of the present invention, there may be provided a QD-VCSEL comprising a substrate, a lower distributed brag reflector (DBR) mirror formed on the substrate, an electron transport layer (ETL) formed on the lower DBR mirror, an emitting layer (EML) formed of nano-particle type group II-VI compound semiconductor quantum dots on the ETL, a hole transport layer (HTL) formed on the EML, and an upper DBR mirror formed on the HTL.

According to another embodiment of the present invention, there is provided a manufacturing method of a QD-VCSEL, comprising preparing a substrate, forming a lower distributed brag reflector (DBR) mirror on the substrate, forming an ETL on the lower DBR mirror, forming an EML by coating nano-particle type group II-VI compound semiconductor quantum dots on the ETL, forming an HTL on the EML, and forming an upper DBR mirror on the HTL.

### BRIEF DESCRIPTION OF THE DRAWINGS

The above and other features and advantages of the present invention will be further described in exemplary embodiments thereof with reference to the attached drawings in which:

FIG. 1 is a sectional view of a quantum dot vertical capacity surface light emitting laser according to an embodiment of the present invention;

FIG. 2 is a sectional view of a quantum dot of a core-shell structure according to the embodiment of the present invention;

FIG. 3 is a graph showing the light emitting wavelength characteristic of the quantum dot vertical capacity surface emitting laser according to the present invention;

FIG. 4 is a graph showing the light emitting wavelength characteristic of a quantum dot device, which is manufactured by the quantum dots so as not to include DBR, including a light emitting layer formed of CdSe-core/ZnS-shell structures; and

FIGS. 5A through 5F are sectional views of the quantum dot vertical capacity surface emitting laser according to an embodiment of the present invention.

### DETAILED DESCRIPTION OF THE EXEMPLARY EMBODIMENTS

FIG. 1 is a sectional view of a quantum dot vertical capacity surface emitting laser (QD-VCSEL) according to an embodiment of the present invention.

Referring to FIG. 1, the QD-VCSEL device according to the embodiment includes a lower distributed brag reflector (DBR) mirror 20, an electron transport layer (ETL) 25, an emitting layer (EML) 30, a hole transport layer (HTL) 35, and an upper DBR mirror 40.

The substrate 10 can be formed of glass and sapphire, instead of semiconductor, and the material of the substrate 10 can vary as will be apparent to those of ordinary skill in the art.

The ETL 25 transports the electrons supplied from the cathode to the EML 30, and the ETL 25 is mainly formed by an Alq₃ or TAZ material.

The HTL 35 transports the holes injected from an anode to the EML 30, and the HTL 35 is mainly formed by α-NPD or TPD material.

The electrons and the holes supplied from the cathode and the anode are recombined in the EML 30 to emit light. In the embodiment of the present invention, the EML 30 is formed of group II-VI compound semiconductor quantum dots 30a of the nano-particle type. In this instance, the quantum dots 30a are referred to as particles having a predetermined size and a quantum confinement effect. The diameter of the quantum dots 30a is approximately 1 to 10 nm. Such quantum dots 30a of the nano-particle type can be synthesized by a chemical wet method. The chemical wet method is referred to as a method of growing particles by inputting precursors to an organic solvent. The method of compounding the quantum dots 30a by the chemical wet method is well known. In the chemical wet method, the organic solvent is commonly provided on the surfaces of the crystals during the growth of the crystals to control the growth of the crystals. Accordingly, the chemical wet method can readily control the size and the uniformity of the nano-particles, compared to a vapour deposition method, such as MOCVD or MBE.

The EML 30 can be formed by a simple layer forming method, such as a spin coating, a deep coating, a printing, or a spray coating. In this case, the emitted light has various colors based on the size of the quantum dots 30a. For example, the lights of various wavelengths according to the quantum size effect, for example, the visible ray band, the blue band, the ultra-violet ray band, are formed by controlling the size of the quantum dots 30a when manufacturing the QD-VCSEL device.

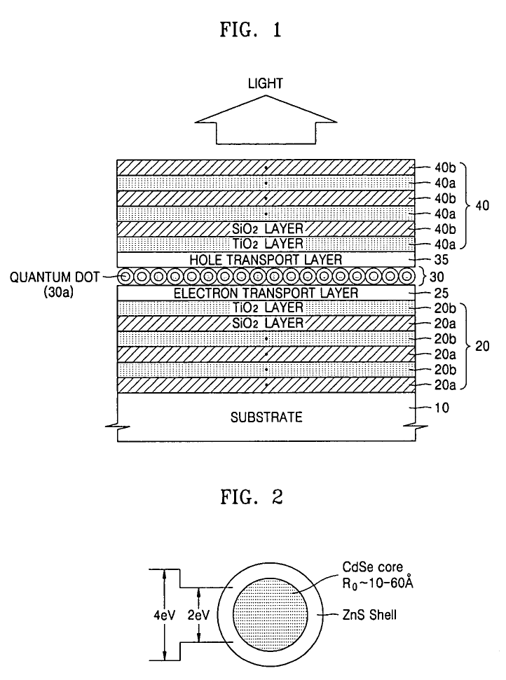

The group II-VI compound semiconductor quantum dots 30a include at least one material selected from the group of CdSe, CdTe, CdS, ZnSe, ZnTe, ZnS, HgTe, and HgS. The group II-VI compound semiconductor quantum dots 30a may be formed in a core-shell structure, which is shown in FIG. 2. In this case, the core includes at least one material selected from the group of CdSe, CdTe, CdS, ZnSe, ZnTe, ZnS, HgTe, and HgS, and the shell includes at least one material selected from the group of CdSe, CdTe, CdS, ZnSe, ZnTe, ZnS, HgTe, and HgS. In this case, the energy band gap of the material of the shell is larger than the energy band gap of the material of the core.

It is known that the upper and lower DBR mirrors 20 and 40 are formed by alternately depositing material layers having a high refractive index and a low refractive index while having a ¼ wavelength thickness, respectively. When a conventional quantum dot optical device is used, it is difficult to control the wavelength compared to a quantum well structure and the full width half maximum of the wavelength is large due to the irregularity of the size of the quantum dots. However, since the VCSEL device according to the embodiment of the present invention includes DBR mirrors 20 and 40 under and on the EML 30, a wavelength having high intensity and narrow full width half maximum can be obtained. In this instance, the material for the lower and upper DBR mirrors 20 and 40 is not critical and materials having a large refractive index difference can be used. When two material layers having a large refractive index difference are deposited repeatedly, the reflective index can be almost one. For example, the lower DBR mirror 20 can be formed of at least one pair of material layers including a SiO₂ layer 20a and a TiO₂ layer 20b. In addition, the upper DBR mirror 40 can be formed of at least one pair of material layers including a TiO₂ layer 20a and a SiO₂ layer 20b.

In the VCSEL device including the conventional epitaxially grown quantum layer, the materials for the substrate and the DBR are selected in order to provide the lattice mismatch with the quantum layer to the epitaxial growth. Accordingly, when a material having a small refractive index is used for the conventional DBR; this results in the increase in the volume of the DBR due to a large amount of stacked material. In addition, when the material for the substrate is a wafer; this results in the limit of the size of the VCSEL device to the size of the wafer. The QD-VCSEL device according to the embodiment of the present invention can solve such shortcomings. Since the EML 30 including the nano-particle type quantum dots 30a is formed by a simple layer forming method, such as spin coating, deep coating, printing, or spray coating, the materials for the substrate and the DBR mirrors are not limited. Therefore, various materials can be used for the substrate and the DBR mirrors. When forming the DBR mirror, two material layers having a large diffractive index difference, for example, TiO₂ and SiO₂ can be selected and alternately formed to reduce the number of stacked layers. When a glass substrate is used for the substrate of the VCSEL device, a large-sized VCSEL device can be manufactured.

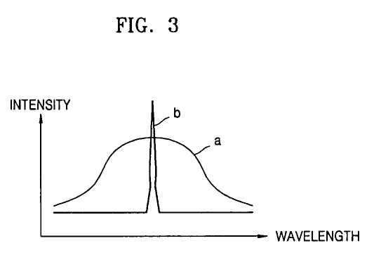

FIG. 3 is a graph showing the light emitting wavelength characteristic of the QD-VCSEL according to the present invention. In the graph of FIG. 3, the light emitting wavelength a of a conventional VCSEL device is shown in comparison with the light emitting wavelength b of a QD-VCSEL device according to the embodiment of the present invention.

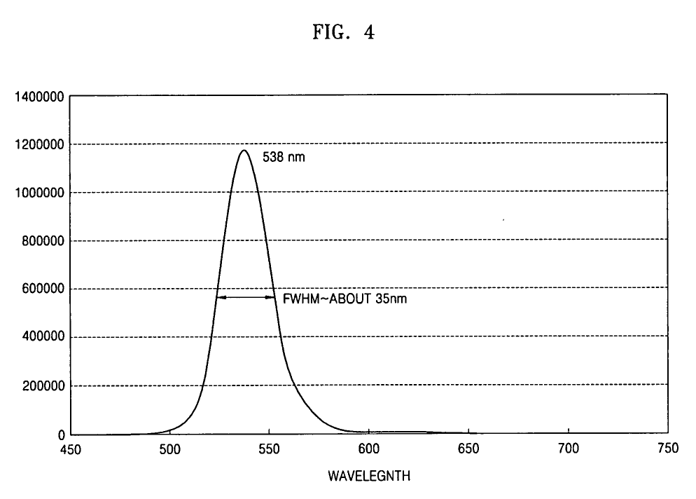

FIG. 4 is a graph showing the light emitting wavelength characteristic of a quantum dot device, which is manufactured by the quantum dots not to include DBR, including an EML formed of CdSe-core/ZnS-shell structures.

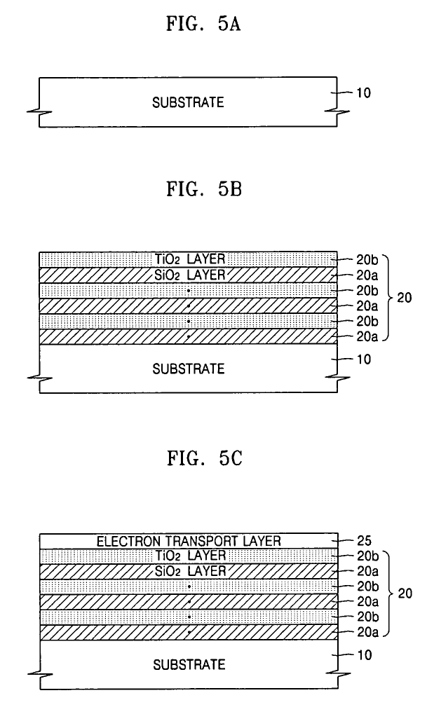

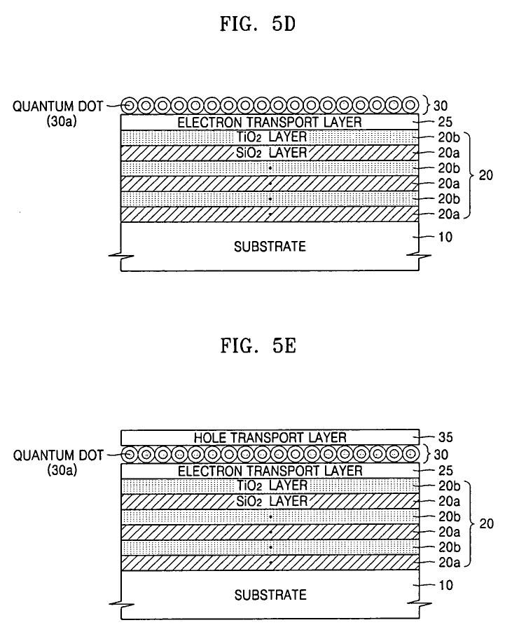

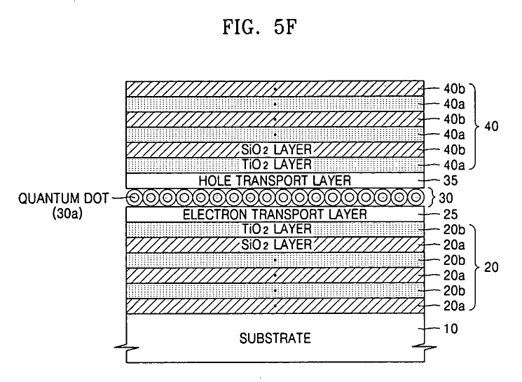

FIGS. 5A through 5F are sectional views of a QD-VCSEL for illustrating a manufacturing process according to the embodiment of the present invention.

Referring to FIGS. 5A and 5B, a substrate 10 is prepared and a lower DBR mirror 20 is formed on the substrate 10. In this case, the lower DBR mirror 20 can be formed by a conventional thin layer forming method, for example, e-beam evaporation or sputtering.

The substrate 10 may be formed of glass or sapphire, as well as a semiconductor. However, the material for the substrate 10 is not restricted.

The material for the lower DBR mirror 20 is not restricted but material layers having a large diffractive index can be used. When two material layers having a large refractive index difference are deposited repeatedly, the reflective index can be almost one. Accordingly, the material layers having a high refractive index and a low refractive index are selected and stacked alternately to a thickness of ¼ wavelength, respectively. For example, the lower DBR mirror 20 is formed of at least one pair of material layers including a SiO₂ layer 20a and a TiO₂ layer 20b.

Referring to FIG. 5C, an ETL 25 is formed on the lower DBR mirror 20. It is known that the ETL 25 is formed of Alq₃ or TaZ material; thus a further description thereof is omitted.

Referring to FIG. 5D, an EML 30 is formed by coating nano-particle type group II-VI compound semiconductor quantum dots 30a on the ETL 25. In this instance, the quantum dots 30a are referred to as particles having a predetermined size and a quantum confinement effect. The diameter of the quantum dots 30a is approximately 1 to 10 nm. The nano-particle type quantum dots 30a can be synthesized by a chemical wet method. The chemical wet method is referred to as a method of growing particles by inputting precursors to an organic solvent, and the method of compounding the quantum dots 30a by the chemical wet method is well known. In the chemical wet method, an organic solvent is commonly provided on the surfaces of the quantum dot crystals to operate as a distributor during the growth of the crystals in order to control the growth of the crystals. Accordingly, the chemical wet method can readily control the size and the uniformity of the nano-particles, compared to a vapor deposition method, such as MOCVD or MBE. One of the primary methods for synthesizing the nano-particles is a colloid method. In this instance, a surfactant is chemically capped on the surfaces of the nano-particles in order to prevent the aggregation of the nano-particles by the Van Der Waals force. And subsequently, the nano-particles are dissolved in a solvent to form a nano-particle colloid solution.

The process of forming the EML layer by coating the quantum dots 30a may be selected from the group of spin coating, deep coating, printing, and spray coating. For example, a solution formed by distributing the quantum dots 30a and a distributor in a polymer solution, for example, CdSe/Poly-3(hexylthiophene) blend can be used as a coating solution. The group II-VI compound semiconductor quantum dots 30a include at least one material selected from the group of CdSe, CdTe, CdS, ZnSe, ZnTe, ZnS, HgTe, and HgS. The group II-VI compound semiconductor quantum dots 30a may be formed in a core-shell structure. In this instance, the core includes at least one material selected from the group of CdSe, CdTe, CdS, ZnSe, ZnTe, ZnS, HgTe, and HgS, and the shell includes at least one material selected from the group of CdSe, CdTe, CdS, ZnSe, ZnTe, ZnS, HgTe, and HgS. The energy band gap of the material for the shell is larger than the energy band gap of the material for the core.

Referring to FIG. 5E, an HTL 35 is formed on the EML 30. It is known that the HTL 35 is formed of α-NPD or TPD material; thus, a further description thereof is omitted.

Referring to FIG. 5F, an upper DBR mirror 40 is formed on the HTL 35. In this instance, the upper DBR mirror 40 can be formed by a conventional thin layer forming method, for example, e-beam evaporation or sputtering. The material for the upper DBR mirror 40 is not critical and material layers having a large diffractive index can be used. Accordingly, the material layers having a high refractive index and a low refractive index are selected and stacked alternately to a thickness of ¼ wavelength, respectively. For example, the upper DBR mirror 40 is formed of at least one pair of material layers including a TiO₂ layer 40a and a SiO₂ layer 40b.

According to the above-described processes, a QD-VCSEL having a high light emitting efficiency and an excellent wavelength characteristic can be formed. In addition, the QD-VCSEL can be manufactured by a straightforward and simple process at a low cost. The lights of various wavelengths according to the quantum size effect, for example, the visible ray band, the blue band, the ultra-violet ray band, can be obtained by controlling the size of the quantum dots when manufacturing the QD-VCSEL device. Since the VCSEL device according to this embodiment of the present invention includes the DBR mirrors under and on the EML, a wavelength having high intensity and narrow full width half maximum can be obtained.

The EML of the QD-VCSEL according to the embodiment of the present invention can be formed by a simple layer forming method, such as a spin coating, a deep coating, a printing, or a spray coating; thus the QD-VCSEL can be manufactured by using simple process steps and at a low cost. In addition, various materials can be used for the substrate and the DBR. When forming the DBR mirror, two material layers having a large diffractive index difference, for example, TiO₂ and SiO₂ can be selected and alternately formed to reduce the number of stacked layers. When a glass substrate is used for the substrate of the QD-VCSEL device, a large QD-VCSEL can be manufactured.

The QD-VCSEL according to an embodiment of the present invention can be utilized in an electroluminescence device.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A quantum dot vertical capacity surface emitting laser (QD-VCSEL) comprising:
a substrate;
a lower distributed brag reflector (DBR) mirror formed on the substrate;
an electron transport layer (ETL) formed on the lower DBR mirror;
an emitting layer (EML) formed of nano-particle type group II-VI compound semiconductor quantum dots on the ETL;
a hole transport layer (HTL) formed on the EML; and
an upper DBR mirror formed on the HTL.

2. The QD-VCSEL of claim 1, wherein the group II-VI compound semiconductor quantum dots include at least one material selected from the group of CdSe, CdTe, CdS, ZnSe, ZnTe, ZnS, HgTe, and HgS.

3. The QD-VCSEL of claim 1, wherein the group II-VI compound semiconductor quantum dots are in a core-shell structure,
wherein, the core includes at least one material selected from the group of CdSe, CdTe, CdS, ZnSe, ZnTe, ZnS, HgTe, and HgS; and
the shell includes at least one material selected from the group of CdSe, CdTe, CdS, ZnSe, ZnTe, ZnS, HgTe, and HgS, and
the energy band gap of the material for the shell is larger than the energy band gap of the material for the core.

4. The QD-VCSEL of claim 1, wherein the diameter of the quantum dots is approximately 1 to 10 nm.

5. A manufacturing method of a QD-VCSEL, the method comprising:
preparing a substrate;
forming a lower distributed brag reflector (DBR) mirror on the substrate;
forming an ETL on the lower DBR mirror;
forming an EML by coating nano-particle type group II-VI compound semiconductor quantum dots on the ETL;
forming an HTL on the EML; and
forming an upper DBR mirror on the HTL.

6. The method of claim 5, wherein the forming of the EML by coating nano-particle group II-VI compound semiconductor quantum dots is performed by a technique selected from the group of spin coating, deep coating, printing, and spray coating.

7. The method of claim 6, wherein the group II-VI compound semiconductor quantum dots include at least one material selected from the group of CdSe, CdTe, CdS, ZnSe, ZnTe, ZnS, HgTe, and HgS.

8. The method of claim 6, wherein the group II-VI compound semiconductor quantum dots are formed in a core-shell structure,
wherein the core includes at least one material selected from the group of CdSe, CdTe, CdS, ZnSe, ZnTe, ZnS, HgTe, and HgS; and
the shell includes at least one material selected from the group formed of CdSe, CdTe, CdS, ZnSe, ZnTe, ZnS, HgTe, and HgS, and
the energy band gap of the material for the shell is larger than the energy band gap of the material for the core.

9. The method of claim 6, wherein the diameter of the quantum dots is approximately 1 to 10 nm.
